(19) United States
(12) Patent Application Publication
(10) Pub. No.: US 2017/0301873 A1
(43) Pub. Date: Oct. 19, 2017

(54) FLEXIBLE CONDUCTIVE FABRIC SUBSTRATE AND METHOD FOR MANUFACTURING SAME

(71) Applicant: KOLON GLOTECH, INC., Gwacheon (KR)

(72) Inventors: Byoung Cheul PARK, Seosan (KR); Beob PARK, Yongin (KR); Soo-Heon KIM, Yongin (KR)

(21) Appl. No.: 15/512,524

(22) PCT Filed: Jan. 28, 2015
(86) PCT No.: PCT/KR2015/000883

§ 371 Date: Mar. 17, 2017

(30) Foreign Application Priority Data
Dec. 30, 2014 (KR) 10-2014-0193557

(51) Int. Cl. H01L 51/00; H01B 1/02; D06M 23/06; D06M 11/83; D06M 11/46; D06M 11/42; C23C 14/58; C23C 14/24; C23C 14/20; C23C 14/08

(52) U.S. Cl. CPC H01L 51/0097; H01B 1/026; H01B 1/023; D06M 23/06; D06M 11/83; C23C 14/087; D06M 11/42; C23C 14/58; C23C 14/24; C23C 14/20; D06M 11/46

(57) ABSTRACT

Disclosed herein is a flexible conductive substrate. According to the present invention, the flexible conductive substrate comprises a fabric substrate, a first film formed of metal or metal oxide on the fabric substrate, a second film formed of ITO film including tin oxide on the first film, and a third film formed of ITO film including tin oxide on the second film. A content of tin oxide included in the second film is smaller than that of oxide included in the third film.

### CROSS-REFERENCE TO RELATED APPLICATIONS

The present specification is a U.S. National Stage of International Patent Application No. PCT/KR2015/000883 filed Jan. 28, 2015, which claims priority to and the benefit of Korean Patent Application No. 10-2014-0193557 filed in the Korean Intellectual Property Office on Dec. 30, 2014, the entire content of which is incorporated herein by reference.

### TECHNICAL FIELD

The present invention relates to a flexible conductive fabric substrate and a method for manufacturing the same, in particularly, a flexible conductive fabric substrate in which a conductive layer is formed on a fabric substrate and a method for manufacturing the same.

### BACKGROUND ART

In general, flexible displays are meant to be flexible, bendable, and rollable through substrates, which are thin and flexible like papers. Such flexible displays have several advantages of light, thin, and unbreakable because they use plastic materials, films, and the like as substrates. For this reason, they have been employed as displays for mobile devices and applications in the field of household or automotive of flexible displays are expected to widen in the future.

In displays devices including flexible displays, devices are formed on substrates. Accordingly, the substrates should have high gas barrier property to secure durability thereof. While a conventional glass substrate used as a display substrate has excellent gas barrier property with respect to penetration of moisture or oxygen, there is a problem in that it is very difficult to embody flexibility. As a result, stainless steel substrates or plastic materials have been widely used. However, these stainless steel substrates or plastic materials are not enough to have flexibility property or bending property.

In addition, there are still application limitations with stainless steel substrates or plastic materials due to their properties. Plastic materials or film substrates, which have low bending resilience and one-side bending property, do not have drape property. Thus, flexible displays using fabric substrates optimizing flexible displays have been studied.

In the meanwhile, transparent conductive substrates are used as displays such as liquid crystal elements, electronic inks, PDP, LCD, OLED, and the like and transparent electrodes of lighting apparatus. Generally, the transparent conductive substrates are formed by stacking metal oxide such as ITO on transparent substrates. However, due to the recent trend of large size in display apparatus, electrodes using a conventional ITO have a problem in that sheet resistance becomes increased and they do not have flexibility.

If sheet resistance becomes increased, it is difficult for voltage to be constantly applied, thereby decreasing homogeneous emission of light. Various techniques to embody low sheet resistance have been tried and a method for doping metal oxide on ITO has been employed. However, doped metal oxide on ITO is a cause to increase a crystallization temperature of ITO films so that it is not easy to apply to flexible substrates for flexible devices.

### SUMMARY OF THE INVENTION

One or more exemplary embodiments overcome the above disadvantages and other disadvantages not described above. However, one or more embodiments are not required to overcome the disadvantages described above, and an exemplary embodiment may not overcome any of the problems described above.

One or more embodiments provide a flexible conductive fabric substrate in which a low-temperature crystallization electrode having high flexibility and low resistance characteristic is formed on a fabric substrate and a method for manufacturing the same.

According to an aspect of one or more embodiments, a flexible conductive fabric substrate comprises a fabric substrate, a first film formed of metal or metal oxide on the fabric substrate, a second film formed of ITO film including tin oxide on the first film, and a third film formed of ITO film including tin oxide on the second film. In this case, a content of tin oxide included in the second film is smaller than that of oxide included in the third film.

In an aspect of one or more embodiments, the fabric substrate comprises a fabric basement formed of at least one or more selected from the group consisting of polyethylene terephthalate, polyethylene naphthalate, polyethylene, nylon, and acryl, an adhesive layer coated on the fabric basement, a film formed of at least one or more selected from the group consisting of polyethylene terephthalate, polyethylene naphthalate, polyethylene, nylon, and acryl, and a planarized layer stacked on the film.

In an aspect of one or more embodiments, the first film formed of metal or metal oxide is formed of at least one or more selected from the group consisting of Ag, Ag+AgOₓ, Al, Al+Al₂O₃, Cu, and CuOₓ.

In an aspect of one or more embodiments, the tin oxide included in the second film is 5 wt. % and less with respect to total weight of the second film.

In an aspect of one or more embodiments, the tin oxide included in the third film is ranged from 7 to 10 wt. % and less with respect to total weight of the third film.

In an aspect of one or more embodiments, a thickness of the first, second, and third films are ranged from 5 to 50 nm, 5 to 30 nm, and 10 to 50 nm, respectively.

In an aspect of one or more embodiments, a planarized coating layer or an inorganic film layer is formed between the fabric substrate and the first film layer.

In an aspect of one or more embodiments, the fabric substrate has a stiffness of 30 to 80 mm and a crease recovery of 100 to 140°.

In an aspect of one or more embodiments, a flexible display apparatus or a flexible lighting apparatus comprising elements of the present invention may be formed.

According to another aspect of one or more embodiments, a method for manufacturing a flexible conductive fabric comprises forming a fabric substrate, forming a first film formed of metal or metal oxide on the fabric substrate, forming a second film formed of ITO film including tin oxide on the first film, and forming a third film formed of ITO film including tin oxide on the second film. In this case, a content of tin oxide included in the second film is smaller than that of oxide included in the third film.

In an aspect of one or more embodiments, forming the fabric substrate comprises forming an adhesive on a fabric basement, forming a film on the fabric basement coated with the adhesive, calendering the fabric basement stacked with the film, and coating a planarized layer on the film.

In an aspect of one or more embodiments, the first film formed of metal or metal oxide is formed of at least one or more selected from the group consisting of Ag, Ag+AgOₓ, Al, Al+Al₂O₃, Cu, and CuOₓ through a vacuum deposition.

In an aspect of one or more embodiments, a heat treatment is further performed with respect to the second and third film layers

In an aspect of one or more embodiments, the heat treatment is performed at a temperature of 25° C. to 150° C.

In an aspect of one or more embodiments, the heat treatment is performed at two times after forming the second and third films.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view showing constitutions of a flexible conductive fabric substrate according to an embodiment of the present invention;

FIG. 2 is a flowchart schematically illustrating a method for manufacturing a flexible conductive fabric substrate according to an embodiment of the present invention;

FIGS. 3A and 3B are based on a photograph of an OLED lighting panel formed on a conductive fabric substrate according to an embodiment of the present invention and shows high flexibility the OLED lighting panel; and

FIG. 4 is based on a photograph of an OLED lighting panel formed on a conductive fabric substrate according to an embodiment of the present invention and shows maintenance of flexibility of the fabric in itself as it is after forming the OLED.

### DETAILED DESCRIPTION

Exemplary embodiments are described in greater detail below with reference to the accompanying drawings.

While this invention has been described in connection with what is presently considered to be the practical and preferred embodiments, it is to be understood that the invention is not limited to the disclosed embodiment, but, on the contrary, is intended to cover various modifications and equivalent arrangements included within the scope of the invention.

The terms “first”, “second”, etc. may be used to describe diverse components, but the components are not limited by the terms. The terms are only used to distinguish one component from the others.

The terms used in this disclosure are only used to describe exemplary embodiments, but are not intended to limit the scope of the disclosure. The singular expression also includes the plural meaning as long as it does not differently mean in the context. In the present application, the terms “include” and “consist of” designate the presence of features, numbers, steps, operations, components, elements, or a combination thereof that are written in the specification, but do not exclude the presence or possibility of addition of one or more other features, numbers, steps, operations, components, elements, or a combination thereof.

Further, in the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions are not described in detail since they would obscure the description with unnecessary detail.

In the drawings, the thickness of layers and regions are exaggerated for clarity. It will be understood that when an element or layer is referred to as being “on” or “above” another element or layer, the element or layer may be directly on another element or layer or intervening elements or layers. Like numbers refer to like elements throughout the specification.

The present inventor have studied about transparent conductive flexible substrates applicable to flexible displays and flexible lightings to develop techniques for lowering a crystallization temperature being a problem in applying ITO films to flexible displays. Thus, it is possible to provide flexible fabric substrates having high flexibility and low resistance.

A flexible conductive fabric substrate according to the present invention comprises a fabric substrate, a first film formed of metal or metal oxide on the fabric substrate, a second film formed of ITO film including tin oxide on the first film, and a third film formed of ITO film including tin oxide on the second film. In this case, a content of tin oxide included in the second film is smaller than that of oxide included in the third film.

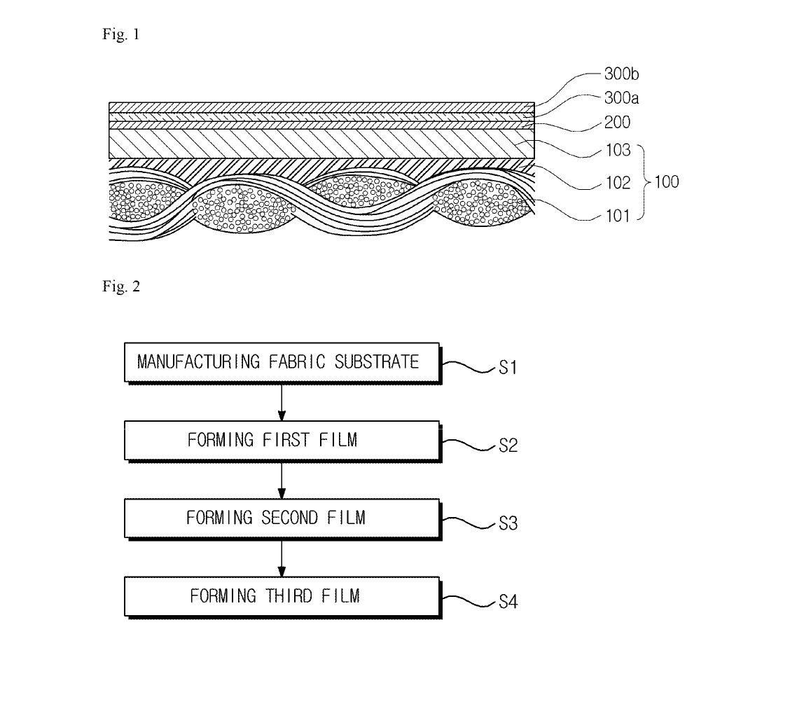

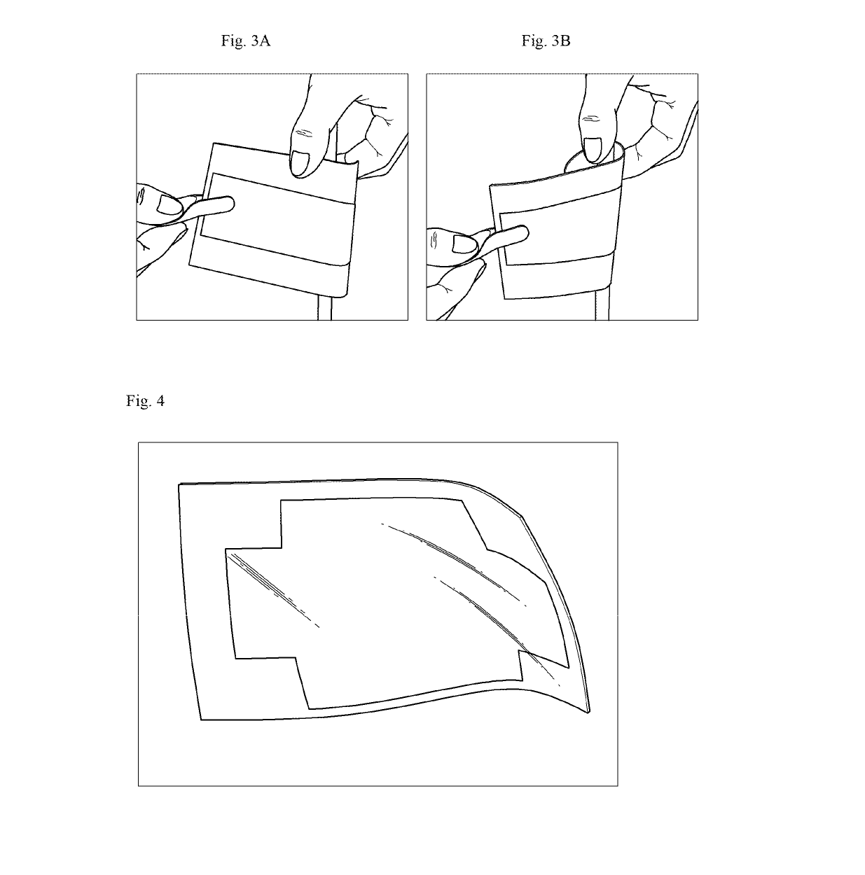

FIG. 1 is a cross-sectional view showing constitutions of a flexible conductive fabric substrate according to an embodiment of the present invention. Referring to FIG. 1, the flexible conductive fabric substrate comprises a fabric substrate 100, a first film 200, a second film 300a, and a third film 300b.

The fabric substrate 100 has stiffness and crease recovery to be able to secure high flexibility by employing a fabric basement 101 as a preform. However, the fabric basement 101 has low surface smoothness. An adhesive layer, a film, and a planarized layer on the fabric basement 101 are stacked to improve surface smoothness.

The fabric basement 101 is formed of at least one or more selected from the group consisting of polyethylene terephthalate, polyethylene naphthalate, polyethylene, nylon, and acryl, concretely, may be woven or non-woven fabrics. The thickness of fabrics does not particularly affect functions thereof. Considering as coating supporting materials and a final substrate thickness, suitable thickness of the fabrics is ranged from 50 μm to 230 μm, preferably ranged from 50 μm to 150 μm, and more preferably ranged from 50 μm to 100 μm.

The adhesive layer is formed of at least one or more selected from the group consisting of acryl-based adhesive, urethane-based adhesive, and silicon-based adhesive. In view of adhesion and total substrate thickness, it is preferable that the thickness of the adhesive layer is ranged from 1 μm to 5 μm.

The film performs a function to impart planarization to the fabric substrate by planarizing the fabric basement 101 and formed of the same materials as the fabric basement 101. When stacking the same materials, they have the same thermal property and accordingly, transformation value by external heat is the same, thereby preventing delamination of a stacked structure. Concretely, the film is formed of at least one or more selected from the group consisting of polyethylene terephthalate, polyethylene naphthalate, polyethylene, nylon, and acryl. It is preferable that the thickness of the film is ranged from 5 μm to 125 μm and surface roughness is ranged from 5 nm to 500 nm. Within the above-mentioned range, planarized substrates can be manufacture without physical property changes such as stiffness, crease recovery, and so forth.

The planarized layer optimizes surface roughness of the fabric substrate and is formed of at least one or more selected from the group consisting of silane, polyurethane, polycarbonate, acrylate-based polymer, epoxy-based polymer, amine-based oligomer, and vinyl-based polymer. The planarized layer has thickness of 0.01 μm to 5 μm and surface roughness of 5 nm to 300 nm, thereby preventing gas barrier layer from not being formed due to substrate difference.

Silane is at least one or more selected from the group consisting of monosilane, disilane, trisilane, and tetrasilane. In addition, silane includes at least one group or more selected from the group consisting of epoxy group, alkoxy group, vinyl group, phenyl group, methacryloxy group, amino group, chlorosilanyl group, chloropropyl group, and mercapto group.

The planarized layer includes at least one or more selected from the group consisting of light absorbing agent, concretely, benzophenone-based, oxalanilide-based, benzotriazole-based, and triazine-based.

In addition, the planarized layer may include inorganic particles. The inorganic particles may be inorganic composite including at least one element or more selected from the group consisting of silicon, aluminum, titanium, and zirconium. The inorganic composite may be metal oxide, non-metal oxide, nitride, or nitrate salt. The inorganic particles preferably have a size of 5 nm to 100 nm because they do not harm surface roughness.

On the fabric substrate formed of the improved planarized fabric basement 101 by stacking the adhesive layer, the film layer and the planarized layer, a barrier layer for protecting moisture and oxygen can be easily formed. For example, as shown in FIG. 1, a planarized coating layer 102 and an inorganic film layer may be further included. The planarized coating layer 102 may be formed for additional planarization and applicable like the above-mentioned planarized layer. The inorganic film layer 103 performs a function to protect gas and has a stacked structure of a SiN layer, a SiO layer, or a silane-based layer, or a sequentially stacked structure thereof at one or more times.

For imparting conductivity, the first film 200, the second film 300a, and the third film 300b are sequentially stacked on the fabric substrate 100 in which the planarized layer and the gas barrier layer are formed.

For embodying low sheet resistance, the first film 200 is formed of metal or metal oxide and concretely, at least one or more selected from the group consisting of Ag, Ag+AgOₓ, Al, Al+Al₂O₃, Cu, and CuOₓ. It is preferable that the first film has a thickness of 5 nm to 50 nm. The first film has a sheet resistance of 1 Ω/□ to 10 Ω/□.

An ITO film including tin oxide is formed on the first film 200. The present inventors identified that if tin oxide is doped with ITO films used as transparent conductive layers, low sheet resistance was obtained. In this case, fabric substrates were provided to embody low resistance. However, while doping tin oxide decreases sheet resistance, there is disadvantages in that if a content of tin oxide becomes increased, crystallization temperature of the ITO film becomes increased. Crystallization means that amorphous film-formed ITO film is transitioned to crystallization film. Crystallization is used to decrease resistance and secure transparency. To improve this, the ITO film is comprised of two films having different tin oxide content in the present invention.

Two ITO films are the second film 300a having low tin oxide content and formed on the first film 200, and the third film 300b having high tin oxide content and formed on the second film 300b. In other words, the second film 300a having low tin oxide content is formed on the first film 200, thereby decreasing crystallization temperature and performing a role as crystallization seed helping crystallization of the third film 300b at a low temperature. The third film 300b has more tin oxide content than the second film 300a to decrease resistance.

The tin oxide included in this second film 300a is ranged from 0 wt. % to 5 wt. % and less with respect to total weight of the second film and preferably, is ranged from 1 wt. % to 3 wt. %.

The tin oxide included in the third film 300b is ranged from 7 wt. % to 10 wt. % and less with respect to total weight of the third film and preferably, is ranged from 7 wt. % to 9 wt. %.

When tin oxide content of 5 wt. % or less is included in the second film 300a, crystallization can be performed under 100° C., and the crystallized second film may help crystallization of the third film. For this reason, the third film can be crystallized at a low temperature. In the meanwhile, tin oxide content is decreased in the second film to lower crystallization temperature, but there is a disadvantage of high resistance. Accordingly, tin oxide content is increased to the third film. That is, if tin oxide content included in the third film is 7 wt. % or less, effect for lowering resistance is small. If tin oxide content included in the third film excesses 10 wt. %, resistance is decreased, but crystallization temperature becomes increased.

Making the second film 300a have a thickness of 5 nm to 30 nm and the third film 300b have a thickness of 10 nm to 50 nm, low crystallization temperature and conductivity are secured.

Next, a method for manufacturing a flexible conductive fabric substrate will be described hereinafter. FIG. 2 is a flowchart schematically illustrating a method for manufacturing a flexible conductive fabric substrate according to an embodiment of the present invention. Referring to FIG. 2, the method comprises forming a fabric substrate (S1), forming a first film formed of metal or metal oxide on the fabric substrate (S2), forming a second film formed of ITO film including tin oxide on the first film (S3), and forming a third film formed of ITO film including tin oxide on the second film (S4).

In advance, forming the fabric substrate (S1) will be described.

The fabric substrate is formed to have constitutions of the above-mentioned fabric substrate 100 so as to have stiffness and crease recovery as well as secure surface smoothness. That is, the fabric substrate is manufactured by forming an adhesive on a fabric basement, forming a film on the fabric basement coated with the adhesive, calendering the fabric basement stacked with the film, and coating a planarized layer on the film. The components of the fabric basement, adhesive, film, planarized layer are applicable to the above-mentioned components and explanation thereof will be omitted to avoid duplicate description.

It is suitable that adhesive is coated in a thickness of 1 μm to 5 μm on the fabric basement through spin coating, slot coating, or bar coating. If surface roughness (Ra) of the fabric basement is over 5 μm, it is preferable that the thickness of the adhesive is ranged from 5 μm to 10 μm. The fabric basement coated with the adhesive is planarized to increase adhesion with the film.

The film is stacked on the fabric basement coated with the adhesive to planarize the fabric basement. As mentioned above, it is preferable that the film is formed of the same material as the fabric basement. The stacking process is performed at a temperature of 50° C. to 150° C., preferably, 70° C. to 150° C., and more preferably, 80° C. to 150° C. and under 2.0 to 5.0 kg/cm². The fabric basement stacked with the film may be additionally provided to an aging step at a temperature of 50° C. to 150° C., preferably, 50° C. to 120° C., and more preferably, 50° C. to 100° C. for 1 to 3 days. Through this, it is possible to minimize delamination between the film and the fabric basement.

The fabric basement stacked with the film is provided to the calendering to improve adhesion and planarization. It is preferable that the calendering is performed at a temperature of 40° C. to 180° C., preferably, 60° C. to 170° C., and more preferably, 70° C. to 160° C. and under 1.5 to 3.5 kg/cm². Within the above-mentioned range, thermal stability of the fabric basement and the adhesion with the stacked film are improved.

Coefficient of thermal expansion (CTE) of the calendered fabric substrate is ranged from 5 to 50 ppm/° C., preferably, 5 to 30 ppm/° C., and more preferably, 5 to 25 ppm/° C. Low CTE imparts improved thermal stability and dimensional stability to the fabric substrate.

In order to optimize surface smoothness of the fabric substrate, the planarized layer is formed on film of the calendered substrate through spin coating, slot coating, or bar coating. Preferably, the planarized layer after coating is cured at a low temperature for forming the planarized layer without thermal transformation of the fabric substrate and optimizing surface smoothness of the fabric substrate. In other words, the planarized layer is cured at a temperature of 80° C. to 160° C., preferably, 80° C. to 140° C., and more preferably, 80° C. to 120° C.

Before the fabric substrate 100 is not provided to a process for forming the conductive layer, it is through a process for forming the inorganic layer to secure moisture and oxygen protection as flexible fabric substrates. Before forming the moisture and the oxygen barrier layer, a planarized layer may be further formed on the fabric substrate to secure surface smoothness.

The fabric substrate 100 including the moisture and the oxygen barrier layer is provided to forming a first film formed of metal or metal oxide on the fabric substrate (S2). The first film formed of metal or metal oxide is formed of at least one or more selected from the group consisting of Ag, Ag+AgOₓ, Al, Al+Al₂O₃, Cu, and CuOₓ through a vacuum deposition. In this case, the vacuum deposition may be performed as well known methods.

The fabric substrate 100 including the first layer is provided to forming a second film formed of ITO film including tin oxide (S3). The second film is formed by making ITO film containing tin oxide of 0 wt. % to 5 wt. % film-formed through a vacuum deposition such as a sputtering method. After forming the second film, a third film is formed by making ITO film containing more tin oxide content, i.e., tin oxide of 7 wt. % to 10 wt. % film-formed through a vacuum deposition such as a sputtering method, thereby obtaining a flexible conductive fabric substrate. In this case, the vacuum deposition may be performed as well known methods.

At this time, to reduce sheet resistance, a heat treatment is further performed with respect to the second and third film layers. The heat treatment for crystallization may be performed after forming the second film or the third film. Preferably, the heat treatment is performed at two times after forming the second and third films.

The heat treatment for crystallization may be performed at a temperature of 25° C. to 150° C. with respect to the second film or the third film. Due to the second film as a crystallization seed, a crystallization heat treatment of the third film may be performed at a temperature of 25° C. to 150° C., which is lower than a conventional temperature.

The flexible conductive fabric substrate of the present invention maintains a stiffness of 30 to 80 nm and a crease recovery of 100 to 140°. In addition, the flexible conductive fabric substrate has high conductivity and low energy bandgap to be conductive substrates of flexible displays embodied by organic light emitting, quantum dot electroluminescence, liquid crystal, electro phoretic layer, and the like and flexible lightings embodied by organic light emitting, quantum dot electroluminescence, LED, and the like.

### EXAMPLE

Acryl-based adhesive with less than 5 μm was coated through a slot coating method on a fabric basement formed of polyethylene naphthalate and having 75 μm thickness. After that, a film formed of polyethylene naphthalate and having 23 μm thickness was stacked at a temperature of 90° C., 2.0 kg/cm², and 60 m/min and then was aged at a temperature of 60° C. for 3 days. Under the condition of 150° C. and 30 kg/cm², the fabric substrate was provided to a calendering process. Silane resins with epoxy group was coated through a slot coating method on a film stacked layer of the fabric substrate and then cured and dried at a temperature of 150° C. for 3 minutes. During the curing process, a planarized layer was shaken to fill geometry of the fabric substrate at the same time. A gas barrier layer in which a SiN layer, a SiO layer, and a silane-based polymer layer are sequentially stacked was formed on the fabric substrate.

Then, a first film was formed by vacuum deposition of Ag in a thickness of 30 nm on the fabric substrate. As a second film, ITO layer containing tin oxide (SnO₂) of 3 wt. % was formed on the first film through a sputtering method. The second film has a thickness of 10 nm. A heat treatment was performed with respect to the second film at a temperature of 100° C. for 1 hour so that the second film was crystallized. Then, a third film was formed with ITO layer containing tin oxide (SnO₂) of 7 wt. % through a sputtering method. The third film has a thickness of 30 nm. A heat treatment was performed with respect to the third film at a temperature of 100° C. for 1 hour so that the second film was crystallized. The relative evaluation properties such as conductivity were given in Table 1.

### COMPARATIVE EXAMPLE

Acryl-based adhesive with less than 5 μm was coated through a slot coating method on a fabric substrate formed of polyethylene naphthalate and having 75 μm thickness. After that, a film formed of polyethylene naphthalate and having 23 μm thickness was stacked at a temperature of 90° C., 2.0 kg/cm², and 60 m/min and then was aged at a temperature of 60° C. for 3 days. Under the condition of 150° C. and 30 kg/cm², the fabric substrate was provided to a calendering process. Silane resins with epoxy group was coated through a slot coating method on a film stacked layer of the fabric substrate and then dried and cured at a temperature of 150° C. for 3 minutes. During the curing process, a planarized layer flowed to fill geometry of the fabric substrate at the same time. A gas barrier layer in which a SiN layer, a SiO layer, and a silane-based polymer layer are sequentially stacked was formed on the fabric substrate.

A flexible conductive fabric substrate was fabricated in the same manner as in Example, except that a conductive layer was not formed to evaluate flexibility of the flexible fabric substrate of Example.

### EVALUATION EXAMPLE

A substrate obtained from Example and Comparative Example was evaluated and an evaluation result was shown in Table 1.

An evaluation was performed by the following methods.

1. Crease Recovery

Crease recovery is a fabric property which indicates the ability of fabric to go back to its original position after creasing. High crease recovery means excellent recovery.

To measure this, a crease recovery test method for fabrics based on KS K 0550 fabric was used. Depending on a test method, a specimen having a size of 4×1.5 was prepared and Monsanto tester was employed. The specimen was inserted between metal substrates and then inserted to a plastic press, 500 g weight was added on the plastic press for 5 minutes. The metal substrates and specimen were inserted to the Monsanto tester. After 5 minutes, an angle of the specimen was read.

2. Stiffness

Stiffness is a criteria of toughness and softness and indicates resistance (flexibility) with respect to a movement of fabrics. Stiffness affects feeling and drapability of fabrics and is measured by Cantilever Method (ISO 4064:2011). According to Cantilever Method, a specimen is placed on an inclined plane of 41.5° and then a touching length of front ends of the specimen is measured. The lower the touching length is, the more excellent the stiffness is.

3. Sheet Resistance and Resistance Change Ratio

Sheet resistance is used to evaluate conductivity, and the sheet resistance of ITO film was measured by Standard Four-Probe Method. The sheet resistance was shown by measuring the change ratio thereof at a bending radius of 3 mm at 30,000 times.

TABLE 1

| | | | | | | Sheet | |
|---|---|---|---|---|---|---|---|
| | | Surface | Crease | | Sheet | Resistance | |
| | Total Thickness | Roughness | Recovery | Stiffness | Resistance | Change Ratio | Transmittance |
| Class | (um) | (Ra, um) | (°) | (mm) | (Ω/□) | (%) | (%, TT) |
| Comparative | 105.00 | 0.083 | 122 | 58 | — | — | 64.3 |
| Example | | | | | | | |
| Example | 105.70 | 0.020 | 120 | 60 | 4.75 | 0.92 | 59.5 |

As shown in Table 1, we found that the fabric substrate according to Example has low sheet resistance and there is little difference between the substrate of Comparative Example and the fabric substrate of Example regarding stiffness and crease recovery. Accordingly, the fabric substrate according to the present invention is capable of securing high conductivity as well as flexibility to be applicable to substrates of various flexible displays or flexible lightings.

According to the present invention, the flexible conductive substrate is capable of having high conductivity at a low temperature and applicable to a fabric substrate due to low energy bandgap so that it can be used as anode in various fields.

In addition, the flexible conductive fabric substrate has excellent flexibility by forming the electrode with thin film and embody high conductivity using metal electrodes.

Furthermore, ITO electrodes that can be crystallized at a low temperature are formed to be applicable to various flexible device substrates having low temperature durability.

Further, ITO is applied on upper layers (the third film) of the electrodes to be applicable high flexible fabric substrates without changing a process in a field in which conventional ITO is used as electrodes.

Further, since conventional display materials are replaced with the fabric substrate thereby increasing design degree of freedom so that the fabric substrate is applicable in various fields.

Further, the fabric substrate has excellent flexibility, elasticity, and skin touch-feeling due to excellent stiffness and crease recovery thereof, so that it is easily applicable to wearable displays.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

1. A flexible conductive fabric substrate comprises:
a fabric substrate;
a first film formed of metal or metal oxide on the fabric substrate;
a second film formed of ITO film including tin oxide on the first film; and
a third film formed of ITO film including tin oxide on the second film,
wherein a content of tin oxide included in the second film is smaller than that of oxide included in the third film.

2. The flexible conductive fabric substrate according to claim 1, wherein the fabric substrate comprises:
a fabric basement formed of at least one or more selected from the group consisting of polyethylene terephthalate, polyethylene naphthalate, polyethylene, nylon, and acryl;
an adhesive layer coated on the fabric basement;
a film formed of at least one or more selected from the group consisting of polyethylene terephthalate, polyethylene naphthalate, polyethylene, nylon, and acryl; and
a planarized layer stacked on the film.

3. The flexible conductive fabric substrate according to claim 1, wherein the first film formed of metal or metal oxide is formed of at least one or more selected from the group consisting of Ag, Ag+AgOₓ, Al, Al+Al₂O₃, Cu, and CuOₓ.

4. The flexible conductive fabric substrate according to claim 1, wherein the tin oxide included in the second film is 5 wt. % and less with respect to total weight of the second film.

5. The flexible conductive fabric substrate according to claim 1, wherein the tin oxide included in the third film is ranged from 7 to 10 wt. % and less with respect to total weight of the third film.

6. The flexible conductive fabric substrate according to claim 1, wherein a thickness of the first, second, and third films are ranged from 5 to 50 nm, 5 to 30 nm, and 10 to 50 nm, respectively.

7. The flexible conductive fabric substrate according to claim 1, wherein a planarized coating layer or an inorganic film layer is formed between the fabric substrate and the first film layer.

8. The flexible conductive fabric substrate according to claim 1, wherein the fabric substrate has a stiffness of 30 to 80 mm and a crease recovery of 100 to 140°.

9. A flexible display apparatus comprising the fabric substrate according to claim 1.

10. A flexible lighting apparatus comprising the fabric substrate according to claim 1.

11. A method for manufacturing a flexible conductive fabric comprises:
forming a fabric substrate;
forming a first film formed of metal or metal oxide on the fabric substrate;
forming a second film formed of ITO film including tin oxide on the first film; and
forming a third film formed of ITO film including tin oxide on the second film,
wherein a content of tin oxide included in the second film is smaller than that of oxide included in the third film.

12. The method according to claim 11, wherein forming the fabric substrate comprises:
forming an adhesive on a fabric basement;
forming a film on the fabric basement coated with the adhesive;
calendering the fabric basement stacked with the film; and
coating a planarized layer on the film.

13. The method according to claim 11, wherein the first film formed of metal or metal oxide is formed of at least one or more selected from the group consisting of Ag, Ag+AgOₓ, Al, Al+Al₂O₃, Cu, and CuOₓ through a vacuum deposition.

14. The method according to claim 11, wherein a heat treatment is further performed with respect to the second or third film layers.

15. The method according to claim 11, wherein the heat treatment is performed at a temperature of 25° C. to 150° C.

16. The method according to claim 11, wherein the heat treatment is performed at two times after forming the second and third films.
